(19) United States
(12) Patent Application Publication
(10) Pub. No.: US 2021/0200469 A1
(43) Pub. Date: Jul. 1, 2021

(54) MEMORY CONTROLLER HAVING DATA COMPRESSOR AND METHOD OF OPERATING THE SAME

(71) Applicant: SK hynix Inc., Gyeonggi-do (KR)

(72) Inventors: Dong Wook KIM, Gyeonggi-do (KR); Hyoung Suk JANG, Seoul (KR)

(21) Appl. No.: 16/909,590

(22) Filed: Jun. 23, 2020

(30) Foreign Application Priority Data
Dec. 30, 2019 (KR) 10-2019-0178416

(51) Int. Cl. G06F 3/06; H03M 7/30

(52) U.S. Cl. CPC G06F 3/0659; G06F 3/0608; H03M 7/30; G06F 3/0673; G06F 3/0656

(57) ABSTRACT

Provided herein may be a memory controller having a data compressor and a method of operating the same. A storage device having improved response speed may include a memory controller that compresses data requested to be written by a host, temporarily stores a larger amount of data requested to be written in a buffer having a limited capacity, decompresses the compressed data, and provides the decompressed data to a memory device.

### CROSS-REFERENCE TO RELATED APPLICATION

The present application claims priority under 35 U.S.C. § 119(a) to Korean patent application number 10-2019-0178416, filed on Dec. 30, 2019, which is incorporated herein by reference in its entirety.

### BACKGROUND

### Field of Invention

Various embodiments of the present disclosure generally relate to an electronic device, and more particularly, to a memory controller and a method of operating the memory controller, which compress or decompress data.

### Description of Related Art

A storage device stores data. The storage device may include a memory device which stores data and a memory controller which controls the memory device. The memory device is a storage implemented using a semiconductor, such as silicon (Si), germanium (Ge), gallium arsenide (GaAs), or indium phosphide (InP). A memory device may be a volatile memory device or a nonvolatile memory device.

In a volatile memory device stored data is lost when power supply is interrupted. Representative examples of a volatile memory device include a static random access memory (SRAM), a dynamic RAM (DRAM), and a synchronous DRAM (SDRAM).

In a nonvolatile memory device stored data is retained even when power supply is interrupted. Representative examples of a nonvolatile memory device include a read only memory (ROM), a programmable ROM (PROM), an electrically programmable ROM (EPROM), an electrically erasable programmable ROM (EEPROM), a flash memory, a phase-change RAM (PRAM), a magnetic RAM (MRAM), a resistive RAM (RRAM), and a ferroelectric RAM (FRAM). A flash memory may be a NOR type or a NAND type.

### SUMMARY

Various embodiments of the present disclosure are directed to a memory controller having improved response speed, and a method of operating the memory controller.

An embodiment of the present disclosure may provide for a memory controller for controlling an operation of a memory device. The memory controller may include a buffer configured to temporarily store data chunks to be stored in the memory device, a data compressor configured to compress data chunks to be stored in the buffer or decompress the data chunks stored in the buffer, and a write controller configured to control the buffer and the data compressor so that original data chunks input from an external host are compressed before being stored in the buffer and compressed data chunks stored in the buffer are decompressed before being provided to the memory device.

An embodiment of the present disclosure may provide for a method of operating a memory device and a memory controller for controlling an operation of the memory device. The method may include receiving original data chunks from an external host, compressing the original data chunks, storing compressed data chunks, generated by compressing the original data chunks, in a buffer, and decompressing the compressed data chunks and providing decompressed data chunks to the memory device.

An embodiment of the present disclosure may provide for a storage device. The storage device may include a memory device, a buffer configured to temporarily store data chunks to be stored in the memory device, and a memory controller configured to compress original data chunks received from an external host and then store the compressed original data chunks in the buffer, decompress the compressed data chunks stored in the buffer and then provide the decompressed data chunks to the memory device, and control operations of the memory device and the buffer so that the decompressed data chunks are stored in the memory device.

An embodiment of the present disclosure may provide for an operating method of a controller, the operating method comprising, compressing an original data chunk to generate a compressed data chunk, buffering, depending on sizes of the original and corresponding compressed data chunks, either original or compressed data chunks in a buffer having a capacity not greater than twice the size of the original data chunk and controlling a memory device to store the original data chunk from the buffer by selectively decompressing the buffered chunk to become the original data chunk, wherein the buffering is performed while responding to the write request for the original data chunk.

### BRIEF DESCRIPTION OF THE DRAWINGS

FIG. 1 is a block diagram illustrating a storage device according to an embodiment of the present disclosure.

FIG. 2 is a diagram illustrating a process for generating data to be stored in a memory device from an original data chunk received from a host.

FIG. 3 is a block diagram illustrating a process in which a memory controller compresses an original data chunk.

FIG. 4 is a diagram illustrating in detail an operation of compressing original data chunks.

FIG. 5 is a diagram illustrating a process for generating meta-information.

FIG. 6 is a diagram illustrating an operation of decompressing compressed data chunks stored in a buffer.

FIG. 7 is a diagram exemplarily illustrating data stored in a buffer.

FIG. 8 is a flowchart illustrating a data compression and decompression operation performed by a memory controller.

FIG. 9 is a flowchart illustrating an operation of storing an original data chunk in a buffer after the original data chunk has been compressed.

FIG. 10 is a flowchart illustrating an operation of decompressing a compressed data chunk stored in a buffer and then providing data to a memory device.

FIG. 11 is a diagram illustrating a memory device 100 according to an embodiment of the present disclosure.

FIG. 12 is a diagram illustrating an embodiment of the memory controller of FIG. 1.

FIG. 13 is a block diagram illustrating a memory card system to which a storage device including a memory device is applied according to an embodiment of the present disclosure.

FIG. 14 is a block diagram illustrating an example of a solid state drive (SSD) system to which a storage device including a memory device is applied according to an embodiment of the present disclosure.

FIG. 15 is a block diagram illustrating a user system to which a storage device including a memory device is applied according to an embodiment of the present disclosure.

### DETAILED DESCRIPTION

Specific structural and functional description provided herein is to describe embodiments of the present disclosure. The present invention, however, may be practiced in various forms and configurations, and thus should not be construed as being limited to the disclosed embodiments.

Various embodiments of the present disclosure are described below with reference to the accompanying drawings, in which preferred embodiments of the present disclosure are shown, so that those skilled in the art can easily practice the present invention. Throughout the specification, reference to “an embodiment,” “another embodiment” or the like is not necessarily to only one embodiment, and different references to any such phrase are not necessarily to the same embodiment(s).

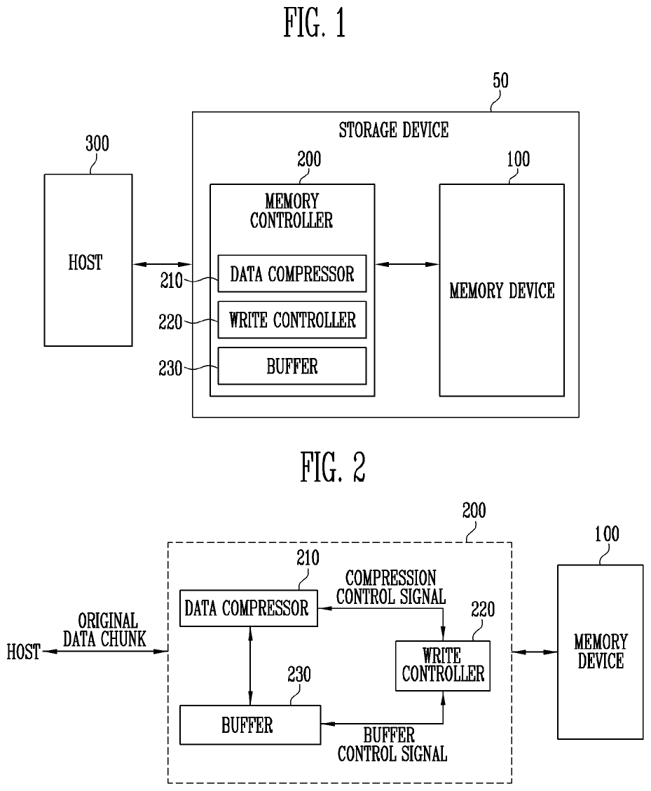

FIG. 1 is a block diagram illustrating a storage device according to an embodiment of the present disclosure.

Referring to FIG. 1, a storage device 50 may include a memory device 100 and a memory controller 200 which controls the operation of the memory device.

The storage device 50 may store data under the control of a host 300, such as a mobile phone, a smartphone, an MP3 player, a laptop computer, a desktop computer, a game console, a TV, a tablet PC, or an in-vehicle infotainment system.

The storage device 50 may be configured as any of various types of storage devices depending on a host interface which is a communication method with the host 300. For example, the storage device 50 may be implemented by a solid state disk (SSD), a multimedia card such as an MMC, an embedded MMC (eMMC), a reduced size MMC (RS-MMC), or a micro-MMC, a secure digital card such as an SD, a mini-SD, or a micro-SD, a universal storage bus (USB) storage device, a universal flash storage (UFS) device, a personal computer memory card international association (PCMCIA) card-type storage device, a peripheral component interconnection (PCI)-card type storage device, a PCI express (PCI-E) card-type storage device, a compact flash (CF) card, a smart media card, and/or a memory stick.

The storage device 50 may be manufactured in any of various types of packages. For example, the storage device 50 may be manufactured as package on package (POP), system in package (SIP), system on chip (SOC), multi-chip package (MCP), chip on board (COB), wafer-level fabricated package (WFP), and/or wafer-level stack package (WSP).

The memory device 100 may store data. The memory device 100 is operated in response to the control of the memory controller 200. The memory device 100 may include a memory cell array including a plurality of memory cells which store data.

Each of the memory cells may be implemented as a single-level cell (SLC) capable of storing one data bit, a multi-level cell (MLC) capable of storing two data bits, a triple-level cell (TLC) capable of storing three data bits, or a quad-level cell (QLC) capable of storing four data bits.

The memory cell array may include a plurality of memory blocks. Each memory block may include a plurality of memory cells. A single memory block may include a plurality of pages. In an embodiment, each page may be a unit by which data is stored in the memory device 100 or by which data stored in the memory device 100 is read. A memory block may be a unit by which data is erased.

In an embodiment, the memory device 100 may take many alternative forms, such as a double data rate synchronous dynamic random access memory (DDR SDRAM), a low power double data rate fourth generation (LPDDR4) SDRAM, a graphics double data rate (GDDR) SDRAM, a low power DDR (LPDDR) SDRAM, a Rambus dynamic random access memory (RDRAM), a NAND flash memory, a vertical NAND flash memory, a NOR flash memory device, a resistive RAM (RRAM), a phase-change memory (PRAM), a magnetoresistive RAM (MRAM), a ferroelectric RAM (FRAM), or a spin transfer torque RAM (STT-RAM). In the present specification, for convenience of description, features and aspects of the invention are described in the context in which the memory device 100 is a NAND flash memory.

The memory device 100 may receive a command and an address from the memory controller 200. The memory device 100 may access an area, selected by the received address, in the memory cell array.

Accessing the selected area may mean that an operation corresponding to the received command is performed on the selected area. For example, the memory device 100 may perform a write operation (i.e., a program operation), a read operation, and an erase operation. During a program operation, the memory device 100 may program data to the area selected by the address. During a read operation, the memory device 100 may read data from the area selected by the address. During an erase operation, the memory device 100 may erase data stored in the area selected by the address.

The memory controller 200 may control the overall operation of the storage device 50.

When power is applied to the storage device 50, the memory controller 200 may run firmware (FW). The firmware (FW) may include a host interface layer (HIL) which receives a request input from the host 300 or outputs a response to the host 300, a flash translation layer (FTL) which manages an operation between the interface of the host 300 and the interface of the memory device 100, and a flash interface layer (FIL) which provides a command to the memory device 100 or receives a response from the memory device 100.

In an embodiment, the memory controller 200 may receive data and a logical address (LA) from the host 300, and may translate the logical address into a physical address (PA) indicating the address of memory cells which are included in the memory device 100 and in which data is to be stored. The logical address may be a logical block address (LBA), and the physical address may be a physical block address (PBA).

The memory controller 200 may control the memory device 100 so that a program operation, a read operation or an erase operation is performed in response to a request received from the host 300. During the program operation, the memory controller 200 may provide a program command, a physical block address, and data to the memory device 100. During the read operation, the memory controller 200 may provide a read command and a physical block address to the memory device 100. During the erase operation, the memory controller 200 may provide an erase command and a physical block address to the memory device 100.

In an embodiment, the memory controller 200 may control the memory device 100 so that a program operation, a read operation or an erase operation is autonomously performed in the absence of a request received from the host 300. For example, the memory controller 200 may control the memory device 100 so that a program operation, a read operation or an erase operation to be used to perform background operations, such as wear leveling, garbage collection, and read reclaim operations, is performed.

Referring to FIG. 1, the memory controller 200 may include a data compressor 210, a write controller 220, and a buffer 230.

Before data requested to be written by the host 300 is stored in the memory device 100, the data may be temporarily stored in the buffer 230. The memory controller 200 may provide a write request completion response to the host 300 in response to a write request from the host 300. Since a time during which data is stored in the buffer 230 is shorter than a time during which the data is stored in the memory device 100, the memory controller 200 may rapidly provide the write request completion response to the host 300. The capacity of the buffer 230 may be limited. Therefore, when data exceeding the capacity of the buffer 230 is input, the time to provide the write request completion response to the host 300 may be delayed.

The data compressor 210 may compress data or decompress the compressed data so as to efficiently use the limited capacity of the buffer 230. The data compressor 210 may compress the data requested to be written by the host 300 before the data requested to be written is temporarily stored in the buffer 230. The buffer 230 may temporarily store the compressed data. Since the size of the compressed data is less than that of the uncompressed data, the buffer 230 may store a larger amount of data requested to be written. The data compressor 210 may decompress the compressed data stored in the buffer 230 so as to generate write data to be stored in the memory device 100. Decompressing and storing the write data in the memory device 100 may decrease the management burden of the memory controller 200.

The write controller 220 may control the data compressor 210 so that the data requested to be written by the host 300 is compressed. The write controller 220 may control the data compressor 210 so that the compressed data is decompressed. The write controller 220 may provide the memory device 100 with the write data to be stored in the memory device 100. The memory device 100 may store the write data.

The buffer 230 may temporarily store the compressed data generated by the data compressor 210. The compressed data stored in the buffer 230 may be decompressed and provided to the memory device 100. Referring to FIG. 1, although the buffer 230 is illustrated as being disposed within the memory controller 200, the buffer 230 may be disposed externally to the memory controller 200. In another embodiment, the buffer 230 is included in the storage device 50 but not in the controller 200. By way of example, the description below is given in the context in which the buffer 230 is a volatile memory.

The host 300 may communicate with the storage device 50 using at least one of various communication methods such as Universal Serial Bus (USB), Serial AT Attachment (SATA), Serial Attached SCSI (SAS), High Speed Interchip (HSIC), Small Computer System Interface (SCSI), Peripheral Component Interconnection (PCI), PCI express (PCIe), Nonvolatile Memory express (NVMe), Universal Flash Storage (UFS), Secure Digital (SD), MultiMedia Card (MMC), embedded MMC (eMMC), Dual In-line Memory Module (DIMM), Registered DIMM (RDIMM), and/or Load Reduced DIMM (LRDIMM) communication methods.

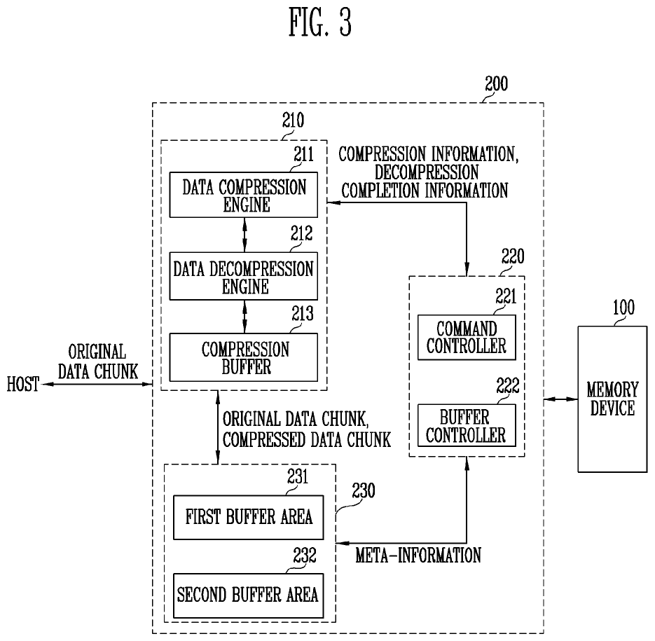

FIG. 2 is a diagram illustrating a process for generating data to be stored in a memory device from an original data chunk received from a host.

Referring to FIG. 2, an original data chunk requested to be written by the host 300 may be input to a memory controller 200, and data generated through a compression and decompression operation performed by the memory controller 200 may be stored in the memory device.

A data compressor 210 may compress the original data chunk requested to be written by the host 300 in response to a compression control signal from a write controller 220. The data may be compressed using any of various data compression techniques, such as packed decimal, relative encoding, character suppression, and Huffman coding, but the present invention is not limited to any particular data compression technique. Any suitable data compression technique may be used. Moreover, the data compressor 210 may be configured to implement any suitable data compression technique.

When the original data chunk is compressed, the data compressor 210 may generate a compressed data chunk, the size of which is smaller than that of the original data chunk. The degree or amount by which the original data chunk is compressed may differ depending on the type of original data chunk. In order to store more data chunks in the buffer 230 having a limited capacity, the original data chunk should be compressed to generate a smaller sized data chunk. Sometimes, in attempting to compress a data chunk, the resulting size is equal to or greater than that of the original data chunk. In this case, the resulting data chunk may be defined as an abnormally compressed data chunk.

The buffer 230 may temporarily store the original data chunk requested to be written by the host 300 in response to a buffer control signal from the write controller 220. Also, the buffer 230 may temporarily store the compressed data chunk generated by the data compressor 210 in response to the buffer control signal from the write controller 220.

The write controller 220 may control the buffer 230 so that the original data chunk or the compressed data chunk is temporarily stored in the buffer 230. The write controller 220 may provide the memory device 100 with a program command, an address, and data to be stored so that the data is stored in the memory device 100. The data provided to the memory device 100 may include the original data chunk, temporarily stored in the buffer 230, or decompressed data of the compressed data chunk, temporarily stored in the buffer 230.

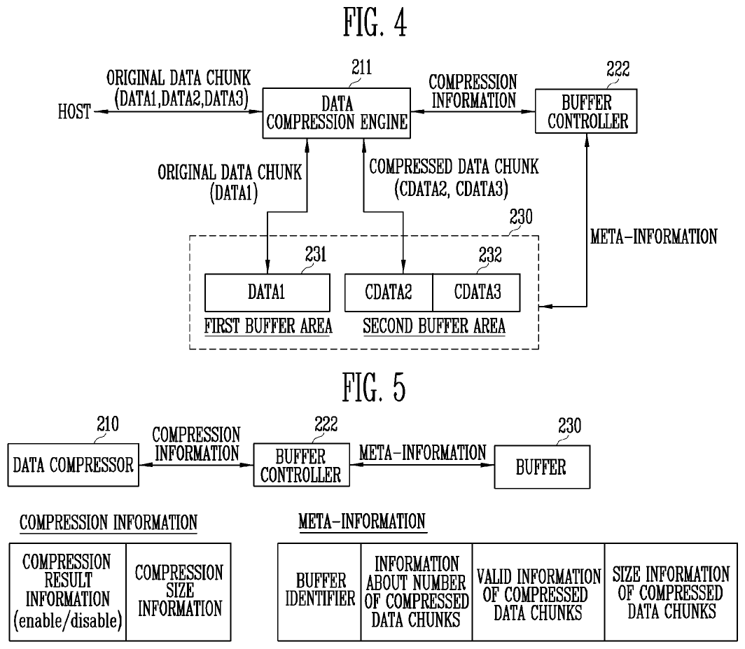

FIG. 3 is a block diagram illustrating a process in which a memory controller compresses an original data chunk.

Referring to FIG. 3, the memory controller 200 may include a data compressor 210, a write controller 220, and a buffer 230.

The data compressor 210 may include a data compression engine 211, a data decompression engine 212, and a compression buffer 213.

The data compression engine 211 may receive a compression control signal provided from a write controller 200 and original data chunks provided from a host. The data compression engine 211 may compress the original data chunks. Compressed data chunks, generated as a result of compression, may temporarily wait in the compression buffer 213. The data compression engine 211 may provide compression information about the result of the compression to the write controller 210. The compression information may include at least one of compression result information and compression size information related to the result of compression of the original data chunks. The compression result information may include at least one of positive information and negative information. The positive information may indicate that the size of each compressed data chunk, generated as the result of the compression, is less than that of the corresponding original data chunk. The negative information may indicate that the size of each compressed data chunk, generated as the result of the compression, is equal to or greater than that of the corresponding original data chunk. That is, the compression information may include compression result information indicating whether the size of the compressed data chunk has decreased as the result of the compression, and compression size information indicating the size of the compressed data chunk, generated as the result of the compression.

The data decompression engine 212 may decompress the compressed data chunks stored in the buffer 230. The compressed data chunks may be the result of the original data chunks having been compressed by the data compression engine 211. When each compressed data chunk is decompressed by the operation of the data decompression engine 212, the decompressed data chunk returns, at least in terms of size, to the corresponding original data chunk. The decompressed data chunks may be provided to the memory device 100. When decompression is completed, the data decompression engine 212 may provide decompression completion information to the write controller 220.

The compression buffer 213 may temporarily store the compressed data chunks that are generated during compression, or decompressed data chunks that are generated during decompression.

The write controller 220 may include a command controller 221 and a buffer controller 222.

The command controller 221 may generate a program command to be provided to the memory device 100 and an address indicating the location at which data is to be stored. The buffer controller 222 may determine data to be temporarily stored in the buffer 230 based on the compression information received from the data compression engine 211. In an embodiment, the buffer controller 222 may control the data compressor 210 and the buffer 230 so that, when the compression information includes positive information, a compressed data chunk having a size less than that of the corresponding original data chunk is stored in the buffer 230. In an embodiment, the buffer controller 222 may control the data compressor 210 and the buffer 230 so that, when the compression information includes negative information, which means that the resulting data was not reduced in size, an original data chunk is stored in the buffer 230. When the compression information includes positive information, the buffer controller 222 may determine compressed data chunks to be stored together in the buffer 230 based on the sizes of the compressed data chunks included in the compression information. For example, it is assumed that the capacity of a first buffer area 231 is 4 KB. Based on the compression information, the buffer controller 222 may identify a plurality of compressed data chunks, the collective size of which approaches 4 KB, and may control the first buffer area 231 so that these compressed data chunks are stored in the first buffer area 231.

The buffer 230 may include a plurality of buffer areas. By way of example, the buffer 230 is shown as having the first buffer area 231 and a second buffer area 232. However, the number of buffer areas is not limited to any particular number. The first buffer area 231 and the second buffer area 232 may sort and separately store the original data chunks and the compressed data chunks. For example, the capacity of each of the first and second buffer areas 231 and 232 may be equal to the size of a single original data chunk. Alternatively, the capacity of each of the first and second buffer areas 231 and 232 may be greater than the size of a single original data chunk, and may be less than the sum of the sizes of two original data chunks. Therefore, in any one of the first and second buffer areas 231 and 232, one or more of the compressed data chunks, the sizes of which have decreased from those of the original data chunks, may be stored. In contrast, in any one of the first and second buffer areas 231 and 232, a single original data chunk may be stored. That is, when the capacity of each of the first and second buffer areas 231 and 232 is equal to the size of a single original data chunk, the original data chunk and the compressed data chunk cannot be stored together in either the first buffer area 231 or the second buffer area 232.

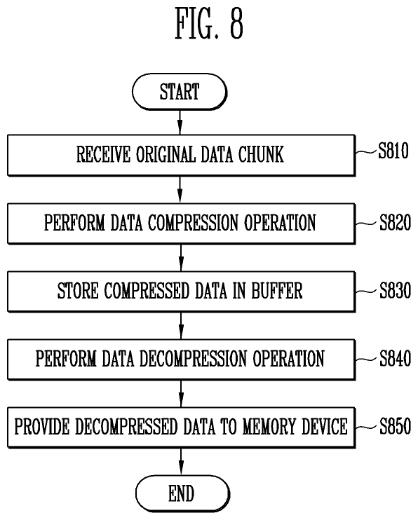

In an embodiment, the buffer 230 may store meta-information provided by the write controller 220. The meta-information may include information indicating the type of data chunk stored in the buffer area. For example, information about whether an original data chunk is stored in the buffer area or whether a compressed data chunk is stored in the buffer area may be included in the meta-information. Also, the meta-information may include the number of compressed data chunks stored in the corresponding buffer area, size information of the compressed data chunks, and valid information of the compressed data chunks. The meta-information is described in detail below with reference to FIG. 7.

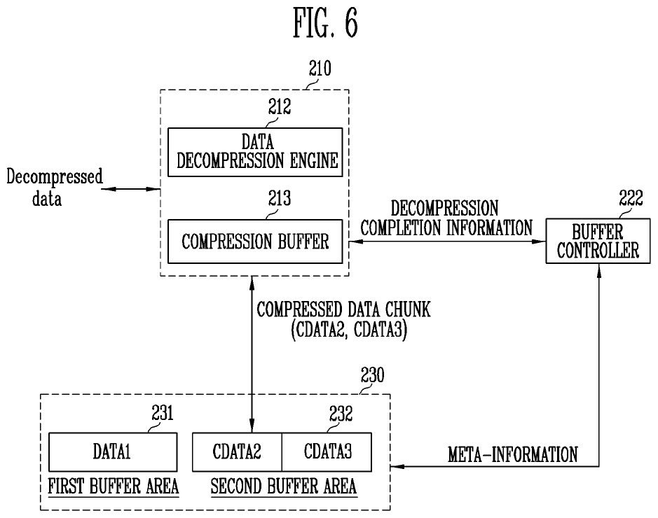

FIG. 4 is a diagram illustrating in detail an operation of compressing original data chunks.

Referring to FIG. 4, original data chunks provided from a host may be input to a data compression engine 211. The data compression engine 211 may individually compress the original data chunks. A buffer 230 may include a first buffer area 231 and a second buffer area 232. The capacity of each buffer area may be equal to the size of a single original data chunk. Alternatively, the capacity of each buffer area may be greater than the size of a single original data chunk, and may be less than the sum of the sizes of two original data chunks. The description below is in the context of each buffer are being equal to the size of a single original data chunk.

A case where the size of a first compressed data chunk (not illustrated) compressed from a first original data chunk by the data compression engine 211 is greater than or at least equal to the size of the first original uncompressed data chunk is assumed. A case where the sizes of a compressed second original data chunk CDATA2 and a compressed third original data chunk CDATA3 are respectively less than those of second and third original uncompressed data chunks DATA2 and DATA3 is assumed. The buffer 230 may include the first buffer area 231 and the second buffer area 232.

As a result of compressing the first original data chunk DATA1, compression information including negative information may be provided to the buffer controller 222. The buffer controller 222 may receive the negative information. Since such negative information indicates that the first original data chunk DATA1 was not reduced in size during compression, the first original data chunk DATA1 may be stored in the first buffer area 231, instead of the non-size-reduced data.

As a result of compressing the second original data chunk DATA2, compression information including positive information may be provided to the buffer controller 222. Also, the compression information may include information about the size of the second compressed data chunk CDATA2 generated by compressing the second original data chunk DATA2. The buffer controller 222 may receive the compression information including the positive information and the size information. Based on the compression information, which indicates that the second compressed data chunk CDATA2 is smaller than DATA2, CDATA2 may be stored in the second buffer area 232.

Next, as a result of compressing a third original data chunk DATA3, compression information including positive information may be provided to the buffer controller 222. Also, the compression information may include information about the size of the third compressed data chunk CDATA3 generated by compressing the third original data chunk DATA3. The buffer controller 222 may receive the compression information including the positive information and the size information. Based on the compression information, the buffer controller 222 may provide the buffer 230 with the third compressed data chunk CDATA3, instead of the third original data chunk DATA3 having a larger size. Also, based on information about the size of the third compressed data chunk CDATA3, the buffer controller 222 may determine whether to store the third compressed data chunk CDATA3 in the second buffer area 232 in which the second compressed data chunk CDATA2 is stored. It is assumed that the capacity of the second buffer area 232 is equal to or greater than the sum of the size of the second compressed data chunk CDATA2 and the size of the third compressed data chunk CDATA3. In this situation, the buffer controller 222 may control the second buffer area 232 so that the third compressed data chunk CDATA3 is stored in the second buffer area 232. That is, in a single buffer of sufficient size (second buffer area 232 in this example), the second compressed data chunk CDATA2 and the third compressed data chunk CDATA3 may be stored together.

The buffer controller 222 may provide meta-information to the buffer 230. The meta-information may indicate the attributes of the data temporarily stored in the buffer 230. Based on the compression information received from the data compression engine 211, the buffer controller 222 may generate the meta-information.

Referring to FIG. 4, in the first buffer area 231, the first original data chunk DATA1 may be stored. Therefore, the buffer controller 222 may generate meta-information indicating the attributes of the first original data chunk DATA1 stored in the first buffer area 231, and may store the meta-information in the first buffer area 231. In the second buffer area 232, the second compressed data chunk CDATA2 and the third compressed data chunk CDATA3 may be stored. Therefore, the buffer controller 222 may generate meta-information indicating the attributes of the second compressed data chunk CDATA2 and the third compressed data chunk CDATA3 which are stored in the second buffer area 232, and may store the meta-information in the second buffer area 232. That is, in respective buffer areas, pieces of meta-information indicating the attributes of the stored data may be stored. The meta-information is described in detail below with reference to FIGS. 5 and 7.

FIG. 5 is a diagram illustrating a process for generating meta-information.

Referring to FIG. 5, a data compressor 210 may compress an original data chunk. The data compressor 210 may generate a compressed data chunk which is a compressed representation of the original data chunk. The data compressor 210 may provide compression information about the compressed data chunk to a buffer controller 222. The buffer controller 222 may generate meta-information based on the received compression information. The buffer controller 222 may provide the meta-information to a buffer 230. The buffer 230 may store the meta-information.

In an example, the compression result information may include at least one of compression result information (positive/negative) and compression size information. The compression result information (positive/negative) may indicate whether or not the size of the compressed data chunk, generated as a result of compression, has decreased from that of the original uncompressed data chunk. Positive compression result information may indicate that the size of the compressed data chunk is less than that of the original data chunk. Negative compression result information may indicate that the size of the compressed data chunk is equal to or greater than that of the original data chunk. The compression size information may indicate the size of the compressed data chunk generated as a result of the compression.

In an embodiment, the meta-information may include at least one of a buffer identifier, information about the number of compressed data chunks, valid information of the compressed data chunks, and size information of the compressed data chunks. The buffer identifier may be, for example, an identification number or a buffer area address, for identifying the corresponding buffer area in the buffer 230. The information about the number of compressed data chunks may indicate the total number of compressed data chunks stored in the buffer area. As described above, since the degree or amount of compression may differ depending on the type of data, the total number of compressed data chunks stored in the buffer area may differ. Therefore, the information about the number of compressed data chunks may indicate the total number of compressed data chunks stored in the corresponding buffer area. The valid information of the compressed data chunks may indicate compressed data chunks provided to the memory device, among the compressed data chunks stored in the buffer area. The compressed data chunks stored in the buffer area are scheduled to be decompressed and stored in the memory device. Therefore, as the compressed data chunks are provided to the memory device, the valid information of the compressed data chunks may be updated. The buffer controller 222 may update the valid information of the compressed data chunks. The size information of the compressed data chunks may include compression size information included in the compression information received from the data compressor 210. Since a plurality of compressed data chunks may be stored in the buffer area depending on the degree of compression of each chunk, the size information of the compressed data chunks may include size information corresponding to each of the compressed data chunks. FIG. 5 is intended to exemplarily explain meta-information, and embodiments of the present invention are not limited thereto.

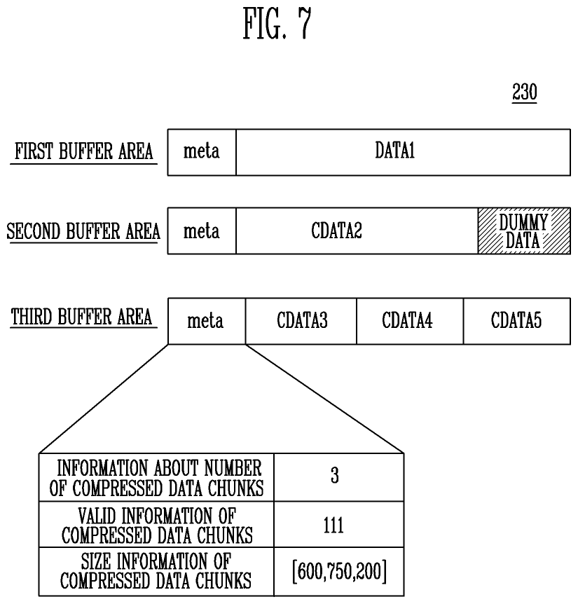

FIG. 6 is a diagram illustrating an operation of decompressing compressed data chunks stored in a buffer.

Referring to FIG. 6, a data compressor 210 may include a data decompression engine 212 and a compression buffer 213. Also, a buffer controller 222 may acquire meta-information stored in a buffer 230, and may then determine whether to decompress stored data.

For example, the buffer controller 222 may acquire meta-information stored in a first buffer area 231. The acquired meta-information may indicate that the data stored in the first buffer area 231 is a first original data chunk DATA1, not compressed data. Therefore, the buffer controller 222 may provide the original data DATA1, stored in the first buffer area 231, to the memory device without decompressing the original data DATA1. The buffer controller 222 may acquire meta-information stored in a second buffer area 232. The acquired meta-information may indicate that the data stored in the second buffer area 232 is a second compressed data chunk CDATA2 and a third compressed data chunk CDATA3 which indicate compressed data. The buffer controller 222 may determine that the second compressed data chunk CDATA2 and the third compressed data chunk CDATA3 are to be decompressed. The data decompression engine 212 may decompress the second compressed data chunk CDATA2, and may provide the decompressed data to the memory device. Further, the data decompression engine 212 may decompress the third compressed data chunk CDATA3, and may provide the decompressed data to the memory device. The data decompressed by the data decompression engine 212 may be temporarily stored in the compression buffer 213. Although, in FIG. 6, the compression buffer 213 is illustrated as being included in the data compressor 210, the present invention is not limited to that configuration; the decompressed data may be temporarily stored in a buffer area included in the buffer 230.

While the data decompression engine 212 decompresses compressed data chunks, the buffer controller 222 may request decompression completion information from the data compressor 210.

When the decompression completion information is received from the data compressor 210, the buffer controller 222 may provide the decompressed data to the memory device. The memory device may store the decompressed data. When the decompression completion information is received, the buffer controller 222 may release the buffer 230. That is, when all of the compressed data chunks stored in one buffer area, among the buffer areas in the buffer 230, are decompressed and provided to the memory device, the corresponding buffer area may be released. The release of the buffer area may be an operation of erasing data that is temporarily stored in the buffer area. Alternatively, the release of the buffer area may include an operation of allowing the buffer to wait to temporarily store data that is subsequently input.

FIG. 7 is a diagram exemplarily illustrating data stored in a buffer.

Referring to FIG. 7, each buffer area may include either an original uncompressed data chunk or a compressed data chunk. Each buffer area may include meta-information indicating the attributes of data stored therein. The meta-information may include information about the number of compressed data chunks stored in the corresponding buffer area, valid information of the compressed data chunks, and size information of the compressed data chunks. Also, the capacity of each buffer area is assumed to be 4 Kbytes.

A first buffer area may include a first original data chunk DATA1 that is not compressed. The meta-information included in the first buffer area may indicate at least one attribute of the first original data chunk DATA1 in the first buffer area. The attribute may be location, for example. That is, the meta-information in the first buffer area may indicate that the original uncompressed data chunk is stored in the first buffer area. In other embodiments, the first buffer area may not include meta-information.

A second buffer area may include a second compressed data chunk CDATA2 in which a second original data chunk (not illustrated) is compressed. Since a compression degree differs depending on the type of data chunk, the size of the second compressed data chunk CDATA2 may not approach the capacity of the second buffer area. Here, when the remaining capacity of the second buffer area is insufficient to store another compressed data chunk, dummy data is included in the second buffer area to fill up the remaining capacity of the second buffer area. The meta-information included in the second buffer area may indicate at least one attribute, e.g., location and size, of the second compressed data chunk CDATA2 in the second buffer area. That is, the meta-information in the second buffer area may indicate that CDATA2 is stored in the second buffer area and may also include information about the size of the second compressed data chunk CDATA2.

A third buffer area may include a third compressed data chunk CDATA3, a fourth compressed data chunk CDATA4, and a fifth compressed data chunk CDATA5. The meta-information may include at least one of information about the number of compressed data chunks, valid information of the compressed data chunks, and size information of the compressed data chunks. That is, the meta-information in the third buffer area may indicate attributes of data chunks stored in the third buffer area. In an embodiment, one attribute indicated may be that the compression size of CDATA3 is 600 bytes, the compression size of CDATA4 is 750 bytes, and the compression size of CDATA5 is 200 bytes. Another attribute indicated may be that there are a total of three compressed data chunks stored. The valid information of the compressed data chunks, which is another attribute that may be indicated, may be 111 meaning that none of three compressed data chunks that are stored are decompressed or provided to the memory device. When any data chunk that is decompressed and provided to the memory device is present among CDATA3, CDATA4, and CDATA5, the valid information of the corresponding compressed data chunk may be updated to ‘0’. The buffer controller may update the valid information of the compressed data chunks. Since the size information of the compressed data chunks indicates a compression size, it may indicate 600,750,200.

FIG. 8 is a flowchart illustrating a data compression and decompression operation performed by a memory controller.

Referring to FIG. 8, at step S810, the memory controller may receive an original data chunk, together with a write request, from an external host. The received original data chunk may be temporarily stored in a buffer before being stored in a memory device. Since a time during which data is stored in the buffer is shorter than a time during which the data is stored in the memory device, the memory controller may provide a fast response to the write request to the host.

At step S820, the memory controller may perform a compression operation of compressing the original data chunk. The degree of compression may differ depending on the type of data. In the case of a certain type of data, the size of data resulting from a compression operation may be equal to or greater than that of the original uncompressed data chunk. In this case, the resulting data chunk may be called an abnormally compressed data chunk. In contrast, in the case of a certain type of data, the size of a compressed data chunk after being compressed may be less than that of an original uncompressed data chunk.

At step S830, the memory controller may provide the buffer with a compressed data chunk, the size of which is less than that of the original uncompressed data chunk. In contrast, when an abnormally compressed data chunk is generated, the memory controller may provide the original uncompressed data chunk to the buffer. The buffer may temporarily store the compressed data chunk or the original data chunk. The buffer has a limited capacity. Thus, when a compressed data chunk according to an embodiment is stored in the buffer, a larger amount of data may be stored compared to an existing scheme, and thus the speed of a response to a write request that is provided to the host may be improved.

At step S840, the memory controller may decompress data chunks that are temporarily stored in the buffer. To reduce management burden on the memory controller, the decompressed data temporarily stored in therein is transferred to the memory device for storage. Therefore, the memory controller may decompress compressed data chunks, among the data chunks temporarily stored in the buffer.

At step S850, the memory controller may provide decompressed data chunks to the memory device. The memory controller may also provide the memory device with a program command and an address indicating the location at which data is to be stored.

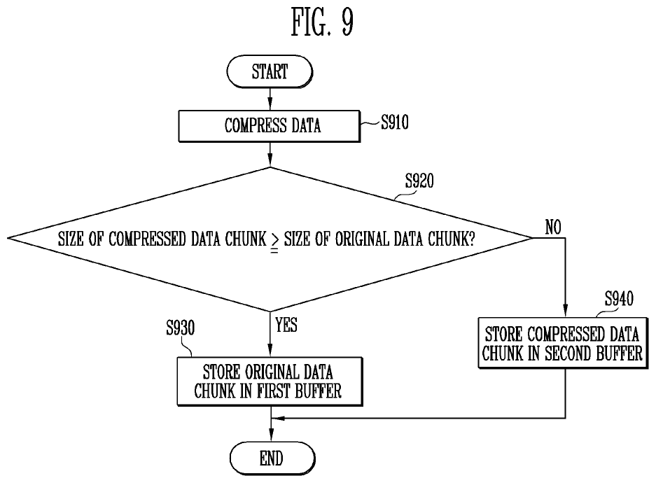

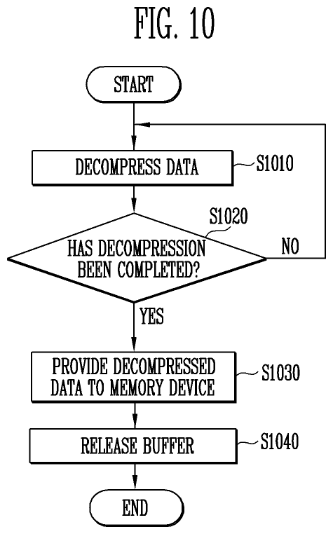

FIG. 9 is a flowchart illustrating an operation of storing an original data chunk in a buffer after the original data chunk has been compressed.

Referring to FIG. 9, at step S910, a data chunk may be compressed by a data compression engine included in the memory controller. Any of various data compression techniques may be used, such as packed decimal, relative encoding, character suppression, and Huffman coding, but the data may be compressed using any suitable data compression technique, and the data compressor 210 may be configured accordingly. As a result of the compression, a compressed data chunk may be generated.

At step S920, the memory controller may compare the size of the compressed data chunk with that of the original data chunk. For respective pieces of data, compression degrees may differ from each other. When the size of the compressed or resulting data chunk is equal to or greater than that of the original uncompressed data chunk, the process may proceed to step S930; otherwise, the process may proceed to step S940.

At step S930, since the size of the resulting data chunk is equal to or greater than that of the original uncompressed data chunk, the memory controller may determine that the resulting data chunk is an abnormally compressed data chunk, and may provide the original data chunk to a first buffer. The first buffer may store the original data chunk. Here, the capacity of the first buffer may be sufficient to store the original data chunk.

At step S940, since the size of the compressed data chunk is less than that of the original uncompressed data chunk, the memory controller may store the compressed data chunk in a second buffer. In accordance with an embodiment of the present disclosure, the compressed data chunk having a smaller size may be stored in the second buffer having a limited capacity, and thus the second buffer may store the compressed data chunk together with other compressed data chunks corresponding to the remaining capacity. Therefore, since a larger amount of data may be stored, a fast response to a write request may be provided to the host.

FIG. 10 is a flowchart illustrating an operation of decompressing a compressed data chunk stored in a buffer and then providing data to a memory device.

Referring to FIG. 10, at step S1010, a data decompression engine included in the memory controller may decompress a compressed data chunk that is temporarily stored in a buffer. Here, since meta-information is included in the buffer, the memory controller may check a buffer in which a compressed data chunk is stored, based on the meta-information. When two or more compressed data chunks are stored in the buffer, the memory controller may decompress the compressed data chunks one by one.

At step S1020, a buffer controller included in the memory controller may determine whether the data decompression engine has completed decompression. In detail, the buffer controller may request decompression completion information, indicating whether decompression has been completed, from the data decompression engine. When information indicating that decompression has not been completed is generated by the data decompression engine, the process may return to step S1010. In contrast, when information indicating that decompression has been completed is generated by the data decompression engine, the process may proceed to step S1030.

At step S1030, the memory controller may provide decompressed data to the memory device. The size of the decompressed data may be equal or equivalent to that of the original uncompressed data. The memory device may perform a program operation of storing the received data.

At step S1040, when the compressed data chunk stored in the buffer is decompressed and is provided to the memory device, the memory controller may release the buffer. The release of the buffer may be an operation of erasing the data that is temporarily stored in the buffer because the data has already been provided to the memory device. Alternatively, the release of the buffer area may include an operation of allowing the buffer to wait to temporarily store data that is subsequently input.

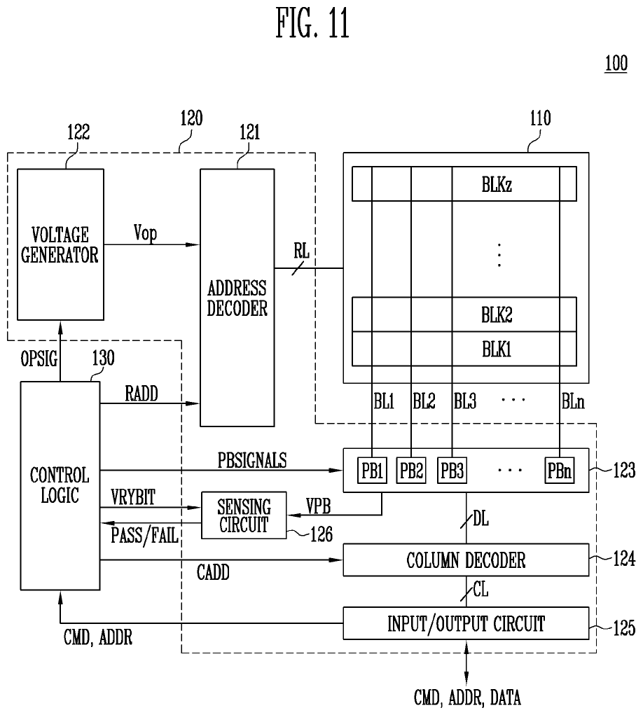

FIG. 11 is a diagram illustrating the memory device 100 according to an embodiment of the present disclosure.

Referring to FIG. 11, the memory device 100 may include a memory cell array 110, a peripheral circuit 120, and control logic 130.

The memory cell array 110 includes a plurality of memory blocks BLK1 to BLKz, which are coupled to an address decoder 121 through row lines RL. Each of the memory blocks BLK1 to BLKz may be coupled to a page buffer group 123 through bit lines BL1 to BLn. Each of the memory blocks BLK1 to BLKz includes a plurality of memory cells. In an embodiment, the plurality of memory cells may be nonvolatile memory cells. Memory cells coupled to the same word line may be defined as a single page. Therefore, a single memory block may include a plurality of pages.

The row lines RL may include at least one source select line, a plurality of word lines, and at least one drain select line.

Each of the memory cells included in the memory cell array 110 may be formed of a single level cell (SLC) capable of storing a single data bit, a multi-level cell (MLC) capable of storing two data bits, a triple-level cell (TLC) capable of storing three data bits, or a quad-level cell (QLC) capable of storing four data bits.

The peripheral circuit 120 may perform a program operation, a read operation, or an erase operation on a selected area of the memory cell array 110 under the control of the control logic 130. The peripheral circuit 120 may drive the memory cell array 110. For example, the peripheral circuit 120 may apply various operating voltages to the row lines RL and the bit lines BL1 to BLn or discharge the applied voltages under the control of the control logic 130.

The peripheral circuit 120 may include the address decoder 121, a voltage generator 122, the page buffer group 123, a column decoder 124, an input/output circuit 125, and a sensing circuit 126.

The address decoder 121 is coupled to the memory cell array 110 through the row lines RL. The row lines RL may include the at least one source select line, the plurality of word lines, and the at least one drain select line. In an embodiment, the word lines may include normal word lines and dummy word lines. In an embodiment, the row lines RL may further include a pipe select line.

The address decoder 121 may be operated under the control of the control logic 130. The address decoder 121 may receive a row address RADD from the control logic 130.

The address decoder 121 may decode the row address RADD received from the control logic 130. The address decoder 121 selects at least one of the memory blocks BLK1 to BLKz according to the decoded address. Further, the address decoder 121 may select at least one word line WL of the selected memory block so that voltages generated by the voltage generator 122 are applied to the at least one word line WL according to the decoded address.

For example, during a program operation, the address decoder 121 may apply a program voltage to a selected word line and apply a program pass voltage having a level lower than that of the program voltage to unselected word lines. During a program verify operation, the address decoder 121 may apply a verify voltage to a selected word line and apply a verify pass voltage higher than the verify voltage to unselected word lines. During a read operation, the address decoder 121 may apply a read voltage to a selected word line and apply a read pass voltage higher than the read voltage to unselected word lines.

In an embodiment, the erase operation of the memory device 100 is performed on a memory block basis. During an erase operation, the address decoder 121 may select one memory block according to the decoded address. During the erase operation, the address decoder 121 may apply a ground voltage to word lines coupled to the selected memory block.

The voltage generator 122 may be operated under the control of the control logic 130. The voltage generator 122 may generate a plurality of voltages using an external supply voltage provided to the memory device. In detail, the voltage generator 122 may generate various operating voltages Vop that are used for program, read, and erase operations in response to an operation signal OPSIG. For example, the voltage generator 122 may generate a program voltage, a verify voltage, a pass voltages, a read voltage, an erase voltage, etc. under the control of the control logic 130.

In an embodiment, the voltage generator 122 may generate an internal supply voltage by regulating the external supply voltage. The internal supply voltage generated by the voltage generator 122 is used as an operating voltage for the memory device 100.

In an embodiment, the voltage generator 122 may generate a plurality of voltages using the external supply voltage or the internal supply voltage.

For example, the voltage generator 122 may include a plurality of pumping capacitors for receiving the internal supply voltage and generate a plurality of voltages by selectively enabling the plurality of pumping capacitors under the control of the control logic 130.

The generated voltages may be supplied to the memory cell array 110 by the address decoder 121.

The page buffer group 123 includes first to n-th page buffers PB1 to PBn, which are coupled to the memory cell array 110 through the first to n-th bit lines BL1 to BLn. The first to n-th page buffers PB1 to PBn are operated under the control of the control logic 130. In detail, the first to n-th page buffers PB1 to PBn may be operated in response to page buffer control signals PBSIGNALS. For example, the first to n-th page buffers PB1 to PBn may temporarily store data received through the first to n-th bit lines BL1 to BLn or may sense voltages or currents of the bit lines BL1 to BLn during a read operation or verify operation.

In detail, during a program operation, when a program pulse is applied to a selected word line, the first to n-th page buffers PB1 to PBn may transfer data DATA, received through the input/output circuit 125, to selected memory cells through the first to n-th bit lines BL1 to BLn. The memory cells in the selected page are programmed based on the received data DATA. Memory cells coupled to a bit line to which a program permission voltage (e.g., a ground voltage) is applied may have increased threshold voltages. The threshold voltages of memory cells coupled to a bit line to which a program inhibit voltage (for example, a supply voltage) is applied may be maintained. During a program verify operation, the first to n-th page buffers PB1 to PBn may read page data from the selected memory cells through the first to n-th bit lines BL1 to BLn.

During a read operation, the first to n-th page buffers PB1 to PBn may read data DATA from the memory cells in the selected page through the first to n-th bit lines BL1 to BLn, and may output the read data DATA to the input/output circuit 125 under the control of the column decoder 124.

During the erase operation, the first to n-th page buffers PB1 to PBn may allow the first to n-th bit lines BL1 to BLn to float.

The column decoder 124 may transfer data between the input/output circuit 125 and the page buffer group 123 in response to a column address CADD. For example, the column decoder 124 may exchange data with the first to n-th page buffers PB1 to PBn through data lines DL or may exchange data with the input/output circuit 125 through column lines CL.

The input/output circuit 125 may transfer a command CMD and an address ADDR, received from the memory controller 200, described with reference to FIG. 1, to the control logic 130, or may exchange the data DATA with the column decoder 124.

During a read operation or a verify operation, the sensing circuit 126 may generate a reference current in response to an enable bit VRYBIT, and may compare a sensing voltage VPB received from the page buffer group 123 with a reference voltage generated using the reference current and then output a pass signal PASS or a fail signal FAIL.

The control logic 130 may control the peripheral circuit 120 by outputting the operation signal OPSIG, the row address RADD, the page buffer control signals PBSIGNALS, and the enable bit VRYBIT in response to the command CMD and the address ADDR. In addition, the control logic 130 may determine whether the verify operation has passed or failed in response to the pass or fail signal PASS or FAIL.

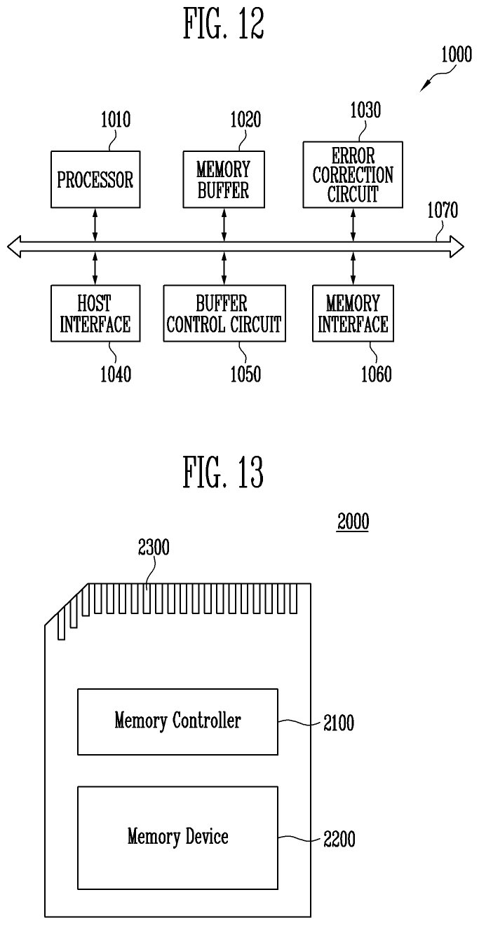

FIG. 12 is a diagram illustrating an embodiment of the memory controller of FIG. 1.

The memory controller 1000 is coupled to a host and a memory device. In response to a request received from the host, the memory controller 1000 may access the memory device.

Referring to FIG. 12, the memory controller 1000 may include a processor 1010, a memory buffer 1020, an error correction circuit (ECC) 1030, a host interface 1040, a buffer control circuit 1050, a memory interface 1060, and a bus 1070.

The bus 1070 may provide a channel between components of the memory controller 1000.

The processor 1010 may control the overall operation of the memory controller 1000 and perform a logical operation. The processor 1010 may communicate with an external host through the host interface 1040 and also communicate with the memory device through the memory interface 1060. Further, the processor 1010 may communicate with the memory buffer 1020 through the buffer control circuit 1050. The processor 1010 may control the operation of the storage device by using the memory buffer 1020 as a working memory, a cache memory or a buffer memory.

The processor 1010 may perform a function of a flash translation layer (FTL). The processor 1010 may randomize data received from the host. For example, the processor 1010 may use a random seed to randomize the data received from the host. The randomized data may be provided, as data to be stored, to the memory device, and may be programmed to a memory cell array.

The processor 1010 may derandomize the data received from the memory device during a read operation. For example, the processor 1010 may derandomize the data received from the memory device using a random seed. The derandomized data may be output to the host.

In an embodiment, the processor 1010 may run software or firmware to perform the randomizing or derandomizing operation.

The memory buffer 1020 may be used as a working memory, a cache memory, or a buffer memory of the processor 1010. The memory buffer 1020 may store codes and commands that are executed by the processor 1010. The memory buffer 1020 may store data that is processed by the processor 1010. The memory buffer 1020 may include a static RAM (SRAM) or a dynamic RAM (DRAM).

The error correction circuit 1030 may perform error correction. The error correction circuit 1030 may perform ECC encoding based on data to be written to the memory device through the memory interface 1060. The ECC-encoded data may be transferred to the memory device through the memory interface 1060. The error correction circuit 1030 may perform ECC decoding based on data received from the memory device through the memory interface 1060. In an example, the error correction circuit 1030 may be included, as the component of the memory interface 1060, in the memory interface 1060.

The host interface 1040 may communicate with the external host under the control of the processor 1010. The host interface 1040 may perform communication using at least one of various communication methods such as Universal Serial Bus (USB), Serial AT Attachment (SATA), Serial Attached SCSI (SAS), High Speed Interchip (HSIC), Small Computer System Interface (SCSI), Peripheral Component Interconnection (PCI), PCI express (PCIe), NonVolatile Memory express (NVMe), Universal Flash Storage (UFS), Secure Digital (SD), MultiMedia Card (MMC), embedded MMC (eMMC), Dual In-line Memory Module (DIMM), Registered DIMM (RDIMM), and/or Load Reduced DIMM (LRDIMM) communication methods.

The buffer control circuit 1050 may control the memory buffer 1020 under the control of the processor 1010.

The memory interface 1060 may communicate with the memory device under the control of the processor 1010. The memory interface 1060 may transmit/receive commands, addresses, and data to/from the memory device through channels.

In an embodiment, the memory controller 1000 may not include the memory buffer 1020 and the buffer control circuit 1050.

In an embodiment, the processor 1010 may control the operation of the memory controller 1000 using codes. The processor 1010 may load codes from a nonvolatile memory device (e.g., ROM) provided in the memory controller 1000. In an embodiment, the processor 1010 may load codes from the memory device through the memory interface 1060.

In an embodiment, the bus 1070 of the memory controller 1000 may be divided into a control bus and a data bus. The data bus may transmit data in the memory controller 1000, and the control bus may transmit control information, such as commands or addresses, in the memory controller 1000. The data bus and the control bus may be separated from each other, such that neither interferes with, nor influences the other. The data bus may be coupled to the host interface 1040, the buffer control circuit 1050, the error correction circuit 1030, and the memory interface 1060. The control bus may be coupled to the host interface 1040, the processor 1010, the buffer control circuit 1050, the memory buffer 1020, and the memory interface 1060.

In an embodiment, the memory buffer 1020 of FIG. 12 may include the buffer 230 of FIG. 1.

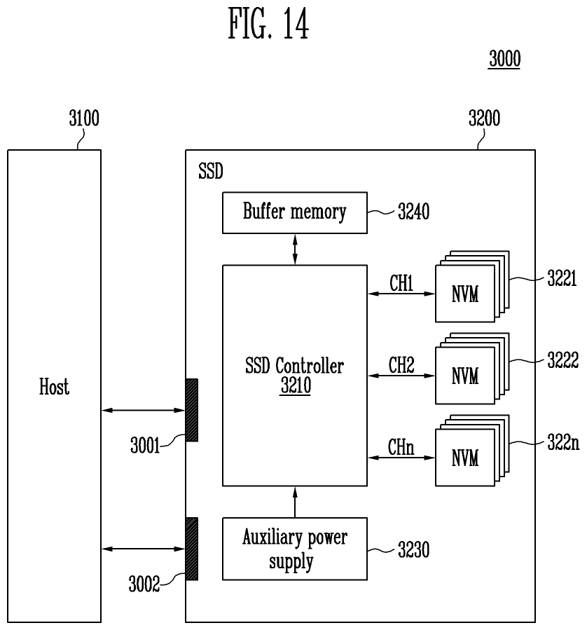

FIG. 13 is a block diagram illustrating a memory card system to which a storage device including a memory device is applied according to an embodiment of the present disclosure.

Referring to FIG. 13, a memory card system 2000 may include a memory controller 2100, a memory device 2200, and a connector 2300.

The memory controller 2100 is coupled to the memory device 2200. The memory controller 2100 may access the memory device 2200. The memory controller 2100 may be implemented in the same way as the memory controller 200, described above with reference to FIG. 1.

In an embodiment, the memory controller 2100 may include components, such as a RAM, a processor, a host interface, a memory interface, and an error correction circuit.

The memory controller 2100 may communicate with an external device through the connector 2300. The memory controller 2100 may communicate with an external device (e.g., a host) based on a specific communication protocol. In an embodiment, the memory controller 2100 may communicate with the external device using at least one of various communication protocols, such as universal serial bus (USB), multimedia card (MMC), embedded MMC (eMMC), peripheral component interconnection (PCI), PCI-express (PCI-E), an advanced technology attachment (ATA), serial-ATA (SATA), parallel-ATA (PATA), small computer small interface (SCSI), enhanced small disk interface (ESDI), integrated drive electronics (IDE), firewire, universal flash storage (UFS), WiFi, Bluetooth, and/or nonvolatile memory express (NVMe) protocols. In an embodiment, the connector 2300 may be defined by at least one of the above-described various communication protocols.

In an embodiment, the memory device 2200 may be implemented as any of various nonvolatile memory devices, such as an Electrically Erasable and Programmable ROM (EEPROM), a NAND flash memory, a NOR flash memory, a Phase-change RAM (PRAM), a Resistive RAM (ReRAM), a Ferroelectric RAM (FRAM), and/or a Spin-Torque Magnetic RAM (STT-MRAM).

In an embodiment, the memory controller 2100 or the memory device 2200 may be packaged in a type such as Package on Package (PoP), Ball grid arrays (BGAs), Chip scale packages (CSPs), Plastic Leaded Chip Carrier (PLCC), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), Wafer-Level Processed Stack Package (WSP), or the like, and may be provided as a single semiconductor package. Alternatively, the memory device 2200 may include a plurality of nonvolatile memory chips, which may be packaged based on any of the above-described package types and may then be provided as a single semiconductor package.

In an embodiment, the memory controller 2100 and the memory device 2200 may be integrated into a single semiconductor device. In an embodiment, the memory controller 2100 and the memory device 2200 may be integrated into a single semiconductor device to form a solid state drive (SSD). In another embodiment, the memory controller 2100 and the memory device 2200 may be integrated into a single semiconductor device to form a memory card, such as a PC card (personal computer memory card international association: PCMCIA), a compact flash card (CF), a smart media card (SM or SMC), a memory stick, a multimedia card (MMC, RS-MMC, MMCmicro or eMMC), a SD card (SD, miniSD, microSD, or SDHC), or a universal flash storage (UFS).

In an embodiment, the memory device 2200 may be the memory device 100, described above with reference to FIG. 1.

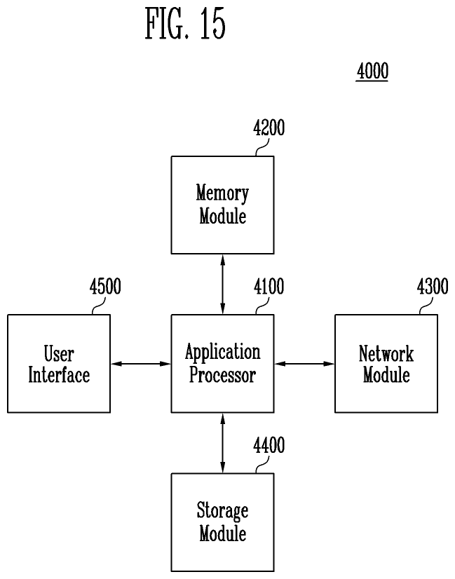

FIG. 14 is a block diagram illustrating an example of a solid state drive (SSD) system to which a storage device including a memory device is applied according to an embodiment of the present disclosure.

Referring to FIG. 14, an SSD system 3000 includes a host 3100 and an SSD 3200. The SSD 3200 may exchange a signal SIG with the host 3100 through a signal connector 3001, and may receive power PWR through a power connector 3002. The SSD 3200 may include an SSD controller 3210, a plurality of flash memories 3221 to 322n, an auxiliary power supply 3230, and a buffer memory 3240.

In an embodiment, the SSD controller 3210 may perform a function of the memory controller 200, described above with reference to FIG. 1.

The SSD controller 3210 may control the plurality of flash memories 3221 to 322n in response to the signal SIG received from the host 3100. In an embodiment, the signal SIG may include signals based on the interfaces of the host 3100 and the SSD 3200. For example, the signal SIG may be defined by at least one of various interfaces such as universal serial bus (USB), multimedia card (MMC), embedded MMC (eMMC), peripheral component interconnection (PCI), PCI-express (PCI-E), an advanced technology attachment (ATA), serial-ATA (SATA), parallel-ATA (PATA), small computer small interface (SCSI), enhanced small disk interface (ESDI), integrated drive electronics (IDE), Firewire, universal flash storage (UFS), WiFi, Bluetooth, and/or nonvolatile memory express (NVMe) interfaces.

The auxiliary power supply 3230 may be coupled to the host 3100 through the power connector 3002. The auxiliary power supply 3230 may be supplied with power PWR from the host 3100 and may be charged with the power PWR. The auxiliary power supply 3230 may supply the power of the SSD 3200 when power from the host 3100 is not smoothly provided. In an embodiment, the auxiliary power supply 3230 may be located within the SSD 3200 or located externally to the SSD 3200. For example, the auxiliary power supply 3230 may be located in a main board, and may also provide auxiliary power to the SSD 3200.

The buffer memory 3240 functions as a buffer memory of the SSD 3200. For example, the buffer memory 3240 may temporarily store data received from the host 3100 or data received from the plurality of flash memories 3221 to 322n, or may temporarily store metadata (e.g., mapping tables) of the flash memories 3221 to 322n. The buffer memory 3240 may include any of various volatile memories, such as DRAM, SDRAM, DDR SDRAM, LPDDR SDRAM, and GRAM, or nonvolatile memories, such as FRAM, ReRAM, STT-MRAM, and/or PRAM.

In an example, each of the nonvolatile memories 3221 to 322n may be the memory device 100, described above with reference to FIG. 1. In an embodiment, the buffer memory 3240 of FIG. 14 may include the buffer 230 of FIG. 1.

FIG. 15 is a block diagram illustrating a user system to which a storage device including a memory device is applied according to an embodiment of the present disclosure.

Referring to FIG. 15, a user system 4000 may include an application processor 4100, a memory module 4200, a network module 4300, a storage module 4400, and a user interface 4500.

The application processor 4100 may run components included in the user system 4000, an Operating System (OS) or a user program. In an embodiment, the application processor 4100 may include controllers, interfaces, graphic engines, etc. for controlling the components included in the user system 4000. The application processor 4100 may be formed of a system-on-chip (SoC).

The memory module 4200 may act as a main memory, a working memory, a buffer memory or a cache memory of the user system 4000. The memory module 4200 may include any of various volatile RAMs, such as DRAM, SDRAM, DDR SDRAM, DDR2 SDRAM, DDR3 SDRAM, LPDDR SDARM, LPDDR2 SDRAM, and LPDDR3 SDRAM or nonvolatile RAMs, such as PRAM, ReRAM, MRAM, and/or FRAM. In an embodiment, the application processor 4100 and the memory module 4200 may be packaged based on a package-on-package (POP), and may then be provided as a single semiconductor package.

The network module 4300 may communicate with external devices. In an embodiment, the network module 4300 may support wireless communication, such as Code Division Multiple Access (CDMA), Global System for Mobile communication (GSM), wideband CDMA (WCDMA), CDMA-2000, Time Division Multiple Access (TDMA), Long Term Evolution (LTE), Wimax, WLAN, UWB, Bluetooth, or Wi-Fi. In an embodiment, the network module 4300 may be included in the application processor 4100.

The storage module 4400 may store data. For example, the storage module 4400 may store data received from the application processor 4100. Alternatively, the storage module 4400 may transmit the data stored in the storage module 4400 to the application processor 4100. In an embodiment, the storage module 4400 may be implemented as a nonvolatile semiconductor memory device, such as a phase-change RAM (PRAM), a magnetic RAM (MRAM), a resistive RAM (RRAM), a NAND flash memory, a NOR flash memory, or a NAND flash memory having a three-dimensional (3D) structure. In an embodiment, the storage module 4400 may be provided as a removable storage medium (removable drive), such as a memory card or an external drive of the user system 4000.

In an embodiment, the storage module 4400 may include a plurality of nonvolatile memory devices, each of which may be configured as the memory device 100, described above with reference to FIG. 1.

The user interface 4500 may include interfaces which input data or instructions to the application processor 4100 or output data to an external device. In an embodiment, the user interface 4500 may include user input interfaces such as a keyboard, a keypad, a button, a touch panel, a touch screen, a touch pad, a touch ball, a camera, a microphone, a gyroscope sensor, a vibration sensor, and/or a piezoelectric element. The user interface 4500 may further include user output interfaces such as a liquid crystal display (LCD), an organic light-emitting diode (OLED) display device, an active matrix OLED (AMOLED) display device, an LED, a speaker, and/or a monitor.

In accordance with embodiments of the present disclosure, a memory controller having improved response speed and a method of operating the memory controller are provided.

While various embodiments of the present invention have been illustrated and described, various modifications are possible as those skilled in the art will recognize. The present invention encompasses all such modifications that fall within the scope of the claims.

What is claimed is:

1. A memory controller for controlling an operation of a memory device, comprising:
a buffer configured to temporarily store data chunks to be stored in the memory device;
a data compressor configured to compress data chunks to be stored in the buffer or decompress the data chunks stored in the buffer; and
a write controller configured to control the buffer and the data compressor so that original data chunks input from an external host are compressed before being stored in the buffer and compressed data chunks stored in the buffer are decompressed before being provided to the memory device.

2. The memory controller according to claim 1, wherein the data compressor comprises a data compression engine configured to compress the original data chunks and generate compression information about the compressed data chunks.

3. The memory controller according to claim 2, wherein the compression information includes at least one of compression result information and compression size information.

4. The memory controller according to claim 3, wherein the compression result information indicates either a positive state in which a size of each compressed data chunk is less than that of a corresponding original uncompressed data chunk or a negative state in which the size of the compressed data chunk is equal to or greater than that of the corresponding original uncompressed data chunk.

5. The memory controller according to claim 4, wherein the write controller is further configured to control the buffer so that the corresponding original uncompressed data chunk is stored in the buffer when the compression result information indicates the negative state.

6. The memory controller according to claim 4, wherein the write controller is further configured to control the buffer so that the compressed data chunk is stored in the buffer when the compression result information indicates the positive state.

7. The memory controller according to claim 6, wherein:
the write controller further comprises a buffer controller configured to generate meta-information about the compressed data chunks that are stored together in the buffer based on the compression result information, and
the buffer controller is further configured to control the buffer so that the meta-information is stored in the buffer.

8. The memory controller according to claim 7, wherein the meta-information includes at least one of size information of the compressed data chunks that are stored together in the buffer and valid information indicating whether the compressed data chunks have been provided to the memory device.

9. The memory controller according to claim 2, wherein the data compressor further comprises a data decompression engine configured to decompress the compressed data chunks to recover the original data chunks, and to provide decompression completion information to the write controller.

10. The memory controller according to claim 9, wherein the write controller further comprises a buffer controller configured to update valid information of compressed data chunks decompressed by the data decompression engine, among the compressed data chunks stored in the buffer.

11. A method of operating a memory controller for controlling an operation of a memory device, the method comprising:
receiving original data chunks from an external host;
compressing the original data chunks;
storing compressed data chunks, generated by compressing the original data chunks, in a buffer; and
decompressing the compressed data chunks and providing decompressed data chunks to the memory device.

12. The method according to claim 11, wherein the compressing of the original data chunks includes generating compression result information in which a size of each original data chunk is compared with a size of a corresponding compressed data chunk or compression size information indicating a size of each compressed data chunk.

13. The method according to claim 12, wherein the compression result information indicates either a positive state in which the size of the corresponding compressed data chunk is less than that of the original uncompressed data chunk or a negative state in which the size of the corresponding compressed data chunk is equal to or greater than that of the original uncompressed data chunk.

14. The method according to claim 13, wherein the storing of a compressed data chunk includes storing the compressed data chunk when the compression result information for that compressed data chunk indicates the positive state.

15. The method according to claim 11, further comprising:
storing, in the buffer, valid information indicating whether the compressed data chunks have been decompressed; and
updating the valid information corresponding to the decompressed data chunks provided to the memory device.

16. A storage device, comprising:
a memory device;
a buffer configured to temporarily store data chunks to be stored in the memory device; and
a memory controller configured to:
compress original data chunks received from an external host and then store the compressed original data chunks in the buffer,
decompress the compressed data chunks stored in the buffer and then provide the decompressed data chunks to the memory device, and
control operations of the memory device and the buffer so that the decompressed data chunks are stored in the memory device.

17. The storage device to claim 16, wherein the memory controller is further configured to generate compression information about the compressed data chunks.

18. The storage device according to claim 17, wherein the compression information includes at least one of compression result information and compression size information.

19. The storage device according to claim 18, wherein the compression result information indicates either a positive state in which a size of each compressed data chunk is less than that of a corresponding original uncompressed data chunk or a negative state in which the size of the compressed data chunk is equal to or greater than that of the corresponding original uncompressed data chunk.

20. The storage device according to claim 19, wherein the memory controller is further configured to:
store the compressed data chunk in the buffer when the compression result information indicates the positive state, and
store the original data chunk in the buffer when the compression result information indicates the negative state.
